(19) United States
(12) Patent Application Publication
(10) Pub. No.: US 2026/0022456 A1
(43) Pub. Date: Jan. 22, 2026

(54) Process Vessel, Processing Apparatus, Substrate Processing Method and Method of Manufacturing Semiconductor Device

(71) Applicant: Kokusai Electric Corporation, Tokyo (JP)

(72) Inventors: Yusaku OKAJIMA, Toyama (JP); Mika URUSHIHARA, Toyama (JP)

(21) Appl. No.: 19/341,194

(22) Filed: Sep. 26, 2025

Related U.S. Application Data
(63) Continuation of application No. PCT/JP2023/035311, filed on Sep. 27, 2023.

(51) Int. Cl. C23C 16/44

(52) U.S. Cl. CPC C23C 16/4412; C23C 16/4408

(57) ABSTRACT

There is provided a technique including: an inner tube provided with an opening through which a process gas is exhausted from a process chamber and a first buffer structure in which a first supplier of the process gas into the process chamber is disposed; an outer tube disposed outside the inner tube; and a second buffer structure provided along the outer tube to be opposite to the opening with the first buffer structure interposed therebetween and surrounded by the inner tube, the outer tube and a side wall of the first buffer structure. When viewed from above, a width of a first gap between an outer wall of the first buffer structure and the outer tube is set to be narrower than a width of a second gap between the inner tube and the outer tube within a region extending from beside the first buffer structure to the opening.

### CROSS REFERENCE TO RELATED APPLICATIONS

This application is a bypass continuation application of PCT International Application No. PCT/JP2023/035311, filed on Sep. 27, 2023, in the WIPO, the entire contents of which are hereby incorporated by reference.

### TECHNICAL FIELD

The present disclosure relates to a process vessel, a processing apparatus, a substrate processing method and a method of manufacturing a semiconductor device.

### BACKGROUND

According to some related arts, as a part of a manufacturing process of a semiconductor device, a substrate processing of forming a film on a substrate may be performed by supplying a source gas and a reactive gas to the substrate. In such a case, by-products may be accumulated when a gas exhausted from a process chamber (hereinafter, such a gas may also be referred to as an “exhaust gas”) stagnates. Thereby, particles may be generated.

### SUMMARY

According to the present disclosure, there is provided a technique capable of suppressing a reversing of an exhaust gas exhausted from a process chamber.

According to an embodiment of the present disclosure, there is provided a technique that includes: an inner tube provided with an opening through which a process gas is exhausted from a process chamber and a first buffer structure in which a first supplier configured to supply the process gas into the process chamber is disposed; an outer tube disposed outside the inner tube; and a second buffer structure provided along the outer tube to be opposite to the opening with the first buffer structure interposed therebetween and surrounded by the inner tube, the outer tube and a side wall of the first buffer structure, wherein, when viewed from above, a width of a first gap formed between an outer wall of the first buffer structure and the outer tube is set to be narrower than a width of a second gap formed between the inner tube and the outer tube within a region extending from beside the first buffer structure to the opening.

### BRIEF DESCRIPTION OF THE DRAWINGS

FIG. 1 is a diagram schematically illustrating a processing apparatus according to one or more embodiments of the present disclosure.

FIG. 2 is a diagram schematically illustrating a horizontal cross-section of a substrate processing furnace used in the processing apparatus according to the embodiments of the present disclosure.

FIG. 3 is a diagram schematically illustrating an enlarged view of a region indicated by an arrow 3X in FIG. 2

FIG. 4 is a diagram schematically illustrating an enlarged view (enlarged view corresponding to FIG. 3) of a second supplier according to a modified example of the embodiments of the present disclosure.

FIG. 5 is a diagram schematically illustrating an enlarged view (enlarged view corresponding to FIG. 3) of a second supplier according to another modified example of the embodiments of the present disclosure.

FIG. 6 is a block diagram schematically illustrating a controller and its related components of the processing apparatus according to the embodiments of the present disclosure.

FIG. 7 is a diagram schematically illustrating a vertical cross-section of an upper portion of a substrate processing furnace used in a processing apparatus according to another embodiment of the present disclosure.

FIG. 8 is a diagram schematically illustrating a horizontal cross-section (corresponding to FIG. 2) of a substrate processing furnace used in a processing apparatus according to still another embodiment of the present disclosure.

### DETAILED DESCRIPTION

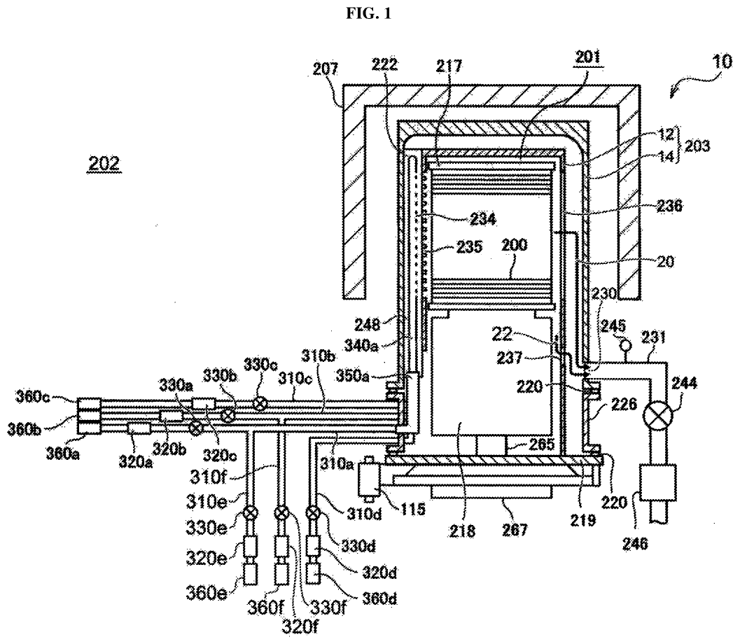

Hereinafter, one or more embodiments (hereinafter, also simply referred to as “embodiments”) according to the present disclosure will be described mainly with reference to FIGS. 1 to 3 and FIG. 6. For example, the drawings used in the following description are all schematic, and a relationship between dimensions of each component and a ratio of each component shown in the drawing may not always match the actual ones. In addition, even between the drawings, the relationship between the dimensions of each component and the ratio of each component may not always match.

A substrate processing apparatus 10 according to the present embodiments, which is an example of a processing apparatus of the present disclosure, includes a process furnace 202. The process furnace 202 is provided with a heater 207 serving as a heating structure. The heater 207 is of a cylindrical shape, and is vertically installed while being supported by a heater base (not shown). The heater 207 also functions as an activator capable of activating a process gas by a heat.

A reaction tube 203 constituting a process vessel is disposed in an inner side of the heater 207 to be aligned in a manner concentric with the heater 207. For example, the reaction tube 203 is made of a heat-resistant material such as quartz (SiO₂) and silicon carbide (SIC).

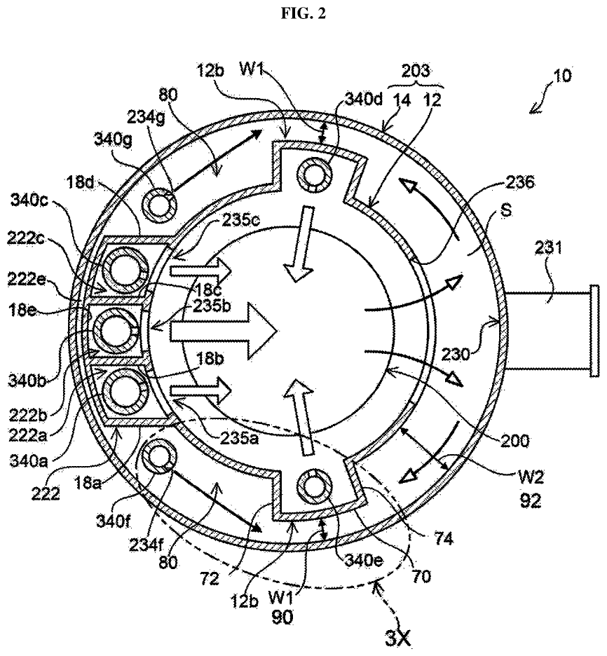

As shown in FIG. 2, the reaction tube 203 includes an inner tube 12 of a cylindrical shape and an outer tube 14 of a cylindrical shape arranged to surround the inner tube 12. The inner tube 12 is disposed in an inner side of the outer tube 14 to be aligned in a manner concentric with the outer tube 14, and a gap S is formed (provided) between the inner tube 12 and the outer tube 14.

As shown in FIG. 1, the inner tube 12 is open at a lower end thereof and closed at an upper end thereof by a flat wall structure. That is, the inner tube 12 is of a cylindrical shape with a ceiling. The outer tube 14 is also open at a lower end thereof and closed at an upper end thereof by a flat wall structure. That is, the outer tube 14 is also of a cylindrical shape with a ceiling.

As shown in FIG. 2, a nozzle arrangement chamber 222 is provided in the gap S formed between the inner tube 12 and the outer tube 14.

At a peripheral wall of the inner tube 12, gas supply slits 235a, 235b and 235c serving as inlet ports are provided.

As shown in FIG. 2, an opening 236 serving as an opening structure is provided in the peripheral wall of the inner tube 12 at a location facing the inlet ports constituted by the gas supply slits 235a, 235b and 235c. In addition, a second gas exhaust port 237 serving as an outlet port whose opening area is smaller than that of the opening 236 is provided below the opening 236.

As shown in FIG. 1, a process chamber 201 is constituted by an inside (inner portion) of the inner tube 12. A plurality of wafers 200 are processed in the process chamber 201. Hereinafter, each of the plurality of wafers 200 may also be referred to as a “wafer 200”. The wafer 200 serves as a substrate.

The process chamber 201 is configured to be capable of accommodating a boat 217 serving as a substrate retainer. The boat 217 is configured to be capable of holding (or supporting) the wafers 200 in a vertical direction while the wafers 200 are horizontally oriented with their centers aligned with one another vertically in a multistage manner. The inner tube 12 surrounds the wafers 200 accommodated in the boat 217.

A lower end of the reaction tube 203 (that is, the lower end of the outer tube 14) is supported by a manifold 226 of a cylindrical shape. For example, the manifold 226 may be made of a metal material such as nickel alloy and stainless steel, or may be made of a heat-resistant material such as quartz (SiO₂) and silicon carbide (SiC). A flange is formed at an upper end of the manifold 226, and the lower end of the outer tube 14 is placed on the flange such that the outer tube 14 can be supported by the flange. An airtight seal 220 such as an O-ring is provided between the flange and the lower end of the outer tube 14. By providing the airtight seal 220, it is possible to keep an inside (inner portion) of the reaction tube 203 airtight.

A seal cap 219 serving as a lid is airtightly attached to an opening at a lower end of the manifold 226 via the airtight seal such as the O-ring. Hereinafter, the opening at the lower end of the manifold 226 may also be referred to as a “lower end opening of the manifold 226”, and the seal cap 219 may also be referred to as a “lid 219”. The lid 219 airtightly closes an opening at the lower end of the reaction tube 203, that is, the lower end opening of the manifold 226. For example, the lid 219 is made of a metal material such as a nickel alloy and stainless steel, and of a disk shape. The lid 219 may be configured such that an outside (outer portion) of the lid 219 is covered with a heat-resistant material such as quartz and SiC.

A boat support table (also referred to as a “boat support stand”) 218 configured to support the boat 217 is provided on the lid 219. For example, the boat support table 218 is made of a heat-resistant material such as quartz and SiC, and functions as a heat insulator.

The boat 217 is vertically provided on the boat support table 218. For example, the boat 217 is made of a heat-resistant material such as quartz and SiC. The boat 217 includes a bottom plate (not shown) fixed to the boat support table 218 and a top plate (not shown) disposed above the bottom plate. A plurality of support columns are provided between the bottom plate and the top plate.

The boat 217 accommodates the wafers 200 to be processed in the process chamber 201 inside the inner tube 12. The wafers 200 are supported by the support columns of the boat 217 while arranged with a fixed interval (distance) therebetween and in a horizontal orientation with their centers aligned. A loading direction (stacking direction) of the wafers 200 is substantially the same as an axial direction of the reaction tube 203.

A boat rotator (which is a boat rotating structure) 267 configured to rotate the boat 217 is provided below the lid 219. A rotating shaft 265 of the boat rotator 267 is connected to the boat support table 218 by penetrating the lid 219. By rotating the rotating shaft 265 of the boat rotator 267, the boat 217 is rotated via the boat support table 218. In addition, by rotating the boat 217, the wafers 200 supported by the boat 217 are also rotated.

The lid 219 is elevated and lowered in the vertical direction by a boat elevator 115 serving as an elevating structure provided outside the reaction tube 203. Thereby, the boat 217 can be transferred (loaded) into and transferred (unloaded) out of the process chamber 201 via the lid 219 by the boat elevator 115.

A plurality of nozzle supports are installed at the manifold 226 so as to penetrate the manifold 226 such that a plurality of gas nozzles 340a, 340b, 340c, 340d and 340c through which gases are supplied into the process chamber 201 can be supported by the nozzle supports. In FIG. 1, the gas nozzle 340a among the gas nozzles 340a, 340b, 340c, 340d and 340e and a nozzle support 350a among the nozzle supports are illustrated. Hereinafter, although not shown in the drawings, a nozzle support related to the gas nozzle 340b may also be referred to as a “nozzle support 350b”, a nozzle support related to the gas nozzle 340c may also be referred to as a “nozzle support 350c”, a nozzle support related to the gas nozzle 340d may also be referred to as a “nozzle support 350d”, and a nozzle support related to the gas nozzle 340e may also be referred to as a “nozzle support 350e”.

According to the present embodiments, for example, five nozzle supports 350a to 350e are installed. For example, each of the nozzle supports 350a to 350c is made of a material such as nickel alloy and stainless steel. As described above, the nozzle support 350a alone is illustrated in the drawings.

Gas supply pipes 310a, 310b and 310c through which the gases are supplied into the process chamber 201 are connected to first ends (first end portions) of the nozzle supports 350a, 350b and 350c, respectively. The nozzle supports 350d and 350e to which the gas nozzles 340d and 340e are connected are unified by a bifurcated pipe (not shown) and connected to a gas supply pipe 310d.

The gas nozzles 340a to 340e are connected to second ends (second end portions) of the nozzle supports 350a to 350e, respectively. As described above, in FIG. 1, the gas nozzle 340a and the nozzle support 350a are illustrated exclusively. For example, each of the gas nozzles 340a to 340e is made of a heat-resistant material such as quartz and SiC.

A reactive gas supply source 360a configured to supply a reactive gas serving as one of process gases, a mass flow controller (also simply referred to as an “MFC”) 320a serving as a flow rate controller and a valve 330a serving as an opening/closing valve are sequentially installed at the gas supply pipe 310a in this order from an upstream side to a downstream side of the gas supply pipe 310a in a gas flow direction.

A source gas supply source 360b configured to supply a source gas serving as one of the process gases, an MFC 320b and a valve 330b are sequentially installed at the gas supply pipe 310b in this order from an upstream side to a downstream side of the gas supply pipe 310b in the gas flow direction. Hereinafter, each of the process gases may also be referred to as “process gas.”

An inert gas supply source 360c configured to supply an inert gas, an MFC 320c and a valve 330c are sequentially installed at the gas supply pipe 310c in this order from an upstream side to a downstream side of the gas supply pipe 310c in the gas flow direction.

An inert gas supply source 360d configured to supply the inert gas, an MFC 320d and a valve 330d are sequentially installed at the gas supply pipe 310d in this order from an upstream side to a downstream side of the gas supply pipe 310d in the gas flow direction.

A gas supply pipe 310e through which the inert gas is supplied is connected to the gas supply pipe 310a at a downstream side of the valve 330a. An inert gas supply source 360e, an MFC 320c and a valve 330e are sequentially installed at the gas supply pipe 310e in this order from an upstream side to a downstream side of the gas supply pipe 310e in the gas flow direction.

A gas supply pipe 310f through which the inert gas is supplied is connected to the gas supply pipe 310b at a downstream side of the valve 330b. An inert gas supply source 360f, an MFC 320f and a valve 330f are sequentially installed at the gas supply pipe 310f in this order from an upstream side to a downstream side of the gas supply pipe 310f in the gas flow direction.

For example, the inert gas supply sources 360c to 360f through which the inert gas is respectively supplied may be connected to a common supply source.

As described above, as the process gas supplied through the gas supply pipe 310a, the reactive gas may be used. In addition, as the process gas supplied through the gas supply pipe 310b, the source gas such as a gas containing silicon (Si) source and a gas obtained by converting a source material containing silicon into a gaseous state may be used. As the inert gas supplied through the gas supply pipes 310c to 310f, nitrogen (N₂) gas may be used. It goes without saying that the source material is not limited to silicon.

An exhaust port 230 is provided at the outer tube 14 of the reaction tube 203. The exhaust port 230 is provided below the second gas exhaust port 237, and is connected to an exhaust pipe 231.

A vacuum pump 246 serving as a vacuum exhaust apparatus is connected to the exhaust pipe 231 via a pressure sensor 245 and an APC (Automatic Pressure Controller) valve 244. The pressure sensor 245 is configured to detect a pressure (inner pressure) of the process chamber 201, and the APC valve 244 serves as a pressure regulator (which is a pressure adjusting structure). The exhaust pipe 231 downstream of the vacuum pump 246 is connected to a component such as a waste gas treatment apparatus (not shown). With such a configuration, by controlling an output of the vacuum pump 246 and an opening degree of the APC valve 244, it is possible to vacuum-exhaust the process chamber 201 such that the inner pressure of the process chamber 201 can be adjusted to a predetermined pressure (that is, a vacuum degree).

For example, the APC valve 244 is constituted by an opening/closing valve configured to be opened or closed to perform a vacuum exhaust operation for the process chamber 201 or stop the vacuum exhaust operation, and further configured to adjust a conductance by adjusting an opening degree thereof to adjust the inner pressure of the process chamber 201.

A temperature sensor (not shown) serving as a temperature detector is provided in the reaction tube 203. By adjusting a power supplied to the heater 207 based on temperature information detected by the temperature sensor, it is possible to set (or adjust) a distribution of the inner temperature of the process chamber 201 close to a desired temperature distribution.

With such a configuration, in the process furnace 202, the boat 217 supporting the wafers 200 (which are to be batch processed) in a multistage manner is transferred (loaded) into the process chamber 201 by the boat support table 218. Then, the wafers 200 loaded into the process chamber 201 are heated to a predetermined temperature by the heater 207 to perform a predetermined processing.

Subsequently, a configuration of the reaction tube 203 will be described with reference to FIGS. 2, 3 and 6.

As shown in FIG. 2, the inner tube 12 is provided with the plurality of gas supply slits 235a, the plurality of gas supply slits 235b and the plurality of gas supply slits 235c through which the gases are supplied to the process chamber 201. The gas supply slits 235a, the gas supply slits 235b and the gas supply slits 235c are configured to connect the nozzle arrangement chamber 222 to the process chamber 201.

In the nozzle arrangement chamber 222, the gap S of a ring shape is formed between an outer peripheral surface of the inner tube 12 and an inner peripheral surface of the outer tube 14. The nozzle arrangement chamber 222 includes a first chamber 222a, a second chamber 222b, and a third chamber 222c. The chambers 222a to 222c are arranged side by side in a circumferential direction of the gap S of the ring shape.

A front wall of the first chamber 222a facing a center of the reaction tube 203 is configured by the peripheral wall of the inner tube 12, a side wall of the first chamber 222a in a circumferential direction thereof is configured by a first partition 18a and a second partition 18b, and a portion of the first chamber 222a facing the outer tube 14 is closed by a connecting wall 18c.

A front wall of the second chamber 222b facing the center of the reaction tube 203 is configured by the peripheral wall of the inner tube 12, a side wall of the second chamber 222b in a circumferential direction thereof is configured by the second partition 18b and a third partition 18c, and a portion of the second chamber 222b facing the outer tube 14 is closed by the connecting wall 18c.

A communication passage 222e communicating between the first chamber 222a and the third chamber 222c is provided (formed) between the connecting wall 18e and a peripheral wall of the outer tube 14.

A front wall of the third chamber 222c facing the center of the reaction tube 203 is configured by the peripheral wall of the inner tube 12, a side wall of the third chamber 222c in a circumferential direction thereof is configured by the third partition 18c and a fourth partition 18d, and a portion of the third chamber 222c facing the outer tube 14 is closed by the connecting wall 18c.

The partitions 18a to 18d and the connecting wall 18e are provided from the upper end to the lower end of the inner tube 12. As a result, a lower end of each of the chambers 222a to 222c is open, and an upper end of each of the chambers 222a to 222c is closed by the wall structure constituting a top surface of the inner tube 12. In other words, each of the chambers 222a to 222c is of a shape with a ceiling.

As shown in FIG. 2, in each of the chambers 222a to 222c of the nozzle arrangement chamber 222, the gas nozzles 340a to 340c extending in an up-down direction (vertical direction) are installed, respectively.

As shown in FIG. 2, the peripheral wall of the inner tube 12 is provided with first buffer structures 12b on both sides of the opening 236, respectively. Hereinafter, each of the first buffer structures 12b may also be referred to as a “first buffer structure 12b”. The first buffer structure 12b is formed by an inner peripheral surface of the inner tube 12 recessed radially outward, and provided in the up-down direction. Specifically, the first buffer structure 12b includes: an outer wall 70 curved in an arc shape when viewed from above; and a pair of side walls 72 and 74.

The outer wall 70 of the first buffer structure 12b is configured to be aligned in a manner concentric with the peripheral wall constituting the outer tube 14. The pair of side walls 72 and 74 are arranged opposite to each other in a circumferential direction of the outer tube 14.

The side wall 72 is located to face the nozzle arrangement chamber 222. In addition, the side wall 74 is located to face the opening 236. The gas nozzle 340d is arranged inside one of the first buffer structures 12b. The gas nozzle 340e is arranged inside the other one of the first buffer structure 12b. The gas nozzles 340d and 340e are examples of a first supplier (which is a first supply structure) configured to be capable of supplying the gas to the process chamber 201. In the present specification, “when viewed from above” refers to “a plan view of a cross-section perpendicular to a central axis of the reaction tube 203”.

Each of the gas nozzles 340a to 340c is provided from a lower portion to an upper portion of the nozzle arrangement chamber 222, and the gas nozzles 340d and 340e are provided lower portions to upper portions of the first buffer structures 12b, respectively. In addition, each of the partitions 18a to 18d of the nozzle arrangement chamber 222 is provided from a ceiling of the nozzle arrangement chamber 222 to above a lower end portion of the reaction tube 203.

Each of the gas nozzles 340a to 340e is configured as an I-shaped long nozzle. A plurality of gas supply holes 234a, a plurality of gas supply holes 234b, a plurality of gas supply holes 234c, a plurality of gas supply holes 234d and a plurality of gas supply holes 234c are provided on side surfaces of the gas nozzles 340a to 340e, respectively. The gas supply holes 234a, the gas supply holes 234b, the gas supply holes 234c, the gas supply holes 234d and the gas supply holes 234c are open toward the center of the reaction tube 203, and the gases are supplied toward a central portion of the reaction tube 203 through the gas supply holes 234a, the gas supply holes 234b, the gas supply holes 234c, the gas supply holes 234d and the gas supply holes 234c, respectively. The gas nozzles 340a to 340c are examples of a third supplier (which is a third supply structure) configured to be capable of supplying the gases to the process chamber 201.

The gas nozzles 340a and 340c are configured to eject the inert gas through the gas supply holes 234a and the gas supply holes 234c, respectively. The gas nozzle 340b is configured to eject the source gas into the second chamber 222b (which is a space between the partitions 18b and 18c corresponding to the gas nozzle 340b). In particular, the gas nozzle 340b is an example of the third supplier configured to be capable of supplying the gas to the process chamber 201 by a flash flow. The gases from each of the gas nozzles 340a to 340c are supplied into the inner tube 12 through the inlet ports (i.e., the gas supply slits 235a to 235c) provided at the inner tube 12 constituting the front wall of each of the chamber 222a to 222c. It is preferable that the inlet ports installed at the inner tube 12 are provided so as to be located between adjacent wafers among the wafers 200, between an uppermost wafer among the wafers 200 capable of being accommodated in the boat 217 and the top plate of the boat 217, and/or between a lowermost wafer among the wafers 200 capable of being accommodated in the boat 217 and the bottom plate of the boat 217.

The opening 236 is arranged such that a region (area) of the process chamber 201 in which the wafers 200 are accommodated is provided between the opening 236 and the nozzle arrangement chamber 222. The opening 236 is provided in the region (wafer region) of the process chamber 201 from a lower end to an upper end thereof.

The second gas exhaust port 237 is provided in the peripheral wall of the inner tube 12 below the opening 236. The opening 236 is provided to communicate between the process chamber 201 and the gap S, and the second gas exhaust port 237 is provided such that an atmosphere (inner atmosphere) of the process chamber 201 at a lower portion thereof is exhausted through the second gas exhaust port 237.

That is, the opening 236 serves as a gas exhaust port through which the atmosphere of the process chamber 201 is exhausted toward the gap S. The gas exhausted through the opening 236 is exhausted from the exhaust pipe 231 to an outside of the reaction tube 203 via the gap S and the exhaust port 230 outside the inner tube 12. In addition, the gas exhausted through the second gas exhaust port 237 is exhausted from the exhaust pipe 231 to the outside of the reaction tube 203 via a lower portion of the gap S and the exhaust port 230.

With such a configuration, the gas after passing the wafer 200 is exhausted via an outside of a cylinder of the inner tube 12. Thereby, by reducing a difference between a pressure of an exhauster (which is an exhaust structure) (such as the vacuum pump 246) and a pressure of the wafer region, it is possible to minimize a pressure loss. In addition, by minimizing the pressure loss, it is possible to lower the pressure of the wafer region and to increase a flow velocity of the gas in the wafer region. As a result, it is possible to mitigate a “loading effect.”

As a result, as shown in FIG. 1, a primary exhaust path (also referred to as a “main exhaust path”) 20 is formed (or provided). An atmosphere (inner atmosphere) of the inner tube 12 is exhausted through the primary exhaust path 20 via the opening 236, the gap S and the exhaust port 230 provided in the outer tube 14.

In addition, as shown in FIG. 1, a secondary exhaust path (also referred to as a “subsidiary exhaust path”) 22 formed (or provided). The inner atmosphere of the inner tube 12 is exhausted to the outside through the secondary exhaust path 22 via the second gas exhaust port 237, the gap S and the exhaust port 230 provided in the outer tube 14.

As shown in FIG. 1, the opening 236 is formed in the wafer region of the inner tube 12, and the process chamber 201 and the gap S are in communication with each other through the opening 236. The second gas exhaust port 237 is provided from a position higher than an upper end of the exhaust port 230 to a position higher than a lower end of the exhaust port 230.

As shown in FIG. 2, the reaction tube 203 is provided with second buffer structures 80 opposite to the opening 236 with the first buffer structures 12b interposed between the opening 236 and the second buffer structures 80 along the outer tube 14 when viewed from above. Hereinafter, each of the second buffer structures 80 may also be referred to as a “second buffer structure 80”. The second buffer structure 80 is provided so as to be surrounded by the inner tube 12, the outer tube 14, and the side wall 74 of the first buffer structure 12b. Specifically, the second buffer structure 80 is provided so as to be surrounded by the outer peripheral surface of the inner tube 12, the inner peripheral surface of the outer tube 14, the side wall 74 of the first buffer structure 12b and the first partition 18a (or the fourth partition 18d).

When viewed from above, the reaction tube 203 is configured such that a width W1 of a first gap 90 provided between the outer wall 70 of the first buffer structure 12b and the inner peripheral surface of the outer tube 14 is set to be narrower than a width W2 of a second gap 92 provided between the outer peripheral surface of the inner tube 12 and the inner peripheral surface of the outer tube 14 within a region extending from beside the outer wall 70 of the first buffer structure 12b to the opening 236. Specifically, the first buffer structure 12b of the reaction tube 203 is configured such that the width W1 of the first gap 90 is set to be narrower than the width W2 of the second gap 92 when viewed from above.

In addition, the first gap 90 is provided between both of the side walls 72 and 74 of the first buffer structure 12b. In other words, the first gap 90 is provided from the side wall 72 to the side wall 74 of the outer wall 70. Thereby, it is possible to reduce a conductance between the outer wall 70 of the first buffer structure 12b and the outer tube 14. As a result, it is possible to suppress a reversing of the gas discharged (exhausted) through the opening 236.

The width W1 of the first gap 90 is configured to be constant along the outer tube 14 when viewed from above. However, the technique of the present disclosure is not limited to such a configuration. For example, the width W1 of the first gap 90 may be configured to narrow toward the second buffer structure 80 along the outer tube 14 when viewed from above.

A gas nozzle 340f serving as a part of a second supplier (which is a second supply structure) configured to supply a purge gas serving as the inert gas is arranged inside one of the second buffer structures 80. In addition, a gas nozzle 340g serving as a part of the second supplier configured to supply the purge gas serving as the inert gas is arranged inside the other one of the second buffer structures 80. Each of the gas nozzles 340f and 340g extends in the up-down direction.

The gas nozzle 340f is provided with a plurality of gas supply holes 234f which are elongated in a length direction of the gas nozzle 340f and arranged at intervals in the length direction. The gas nozzle 340f is configured such that the purge gas is supplied through the gas nozzle 340f toward the first gap 90 corresponding to a lower one of the first buffer structures 12b in FIG. 2. That is, an ejection direction of the purge gas through the gas nozzle 340f is directed toward the first gap 90 corresponding to the lower one of the first buffer structures 12b. More specifically, the gas supply holes 234f are open toward the first gap 90 corresponding to the lower one of the first buffer structures 12b.

The gas nozzle 340g is provided with a plurality of gas supply holes 234g which are elongated in a length direction of the gas nozzle 340g and arranged at intervals in the length direction. The gas nozzle 340g is configured such that the purge gas is supplied through the gas nozzle 340g toward the first gap 90 corresponding to an upper one of the first buffer structures 12b in FIG. 2. That is, an ejection direction of the purge gas through the gas nozzle 340g is directed toward the first gap 90 corresponding to the upper one of the first buffer structures 12b. More specifically, the gas supply holes 234g are open toward the first gap 90 corresponding to the upper one of the first buffer structures 12b. In addition, according to the present embodiments, a flow path diameter (pipe diameter) of the gas nozzle 340f is the same as that of the gas nozzle 340g.

In addition, the width W1 of the first gap 90 is configured to be smaller than a flow path diameter D of each of the gas nozzles 340f and 340g. Further, an amount of protrusion H of the first buffer structure 12b from the inner tube 12 is configured to be larger than the flow path diameter D of each of the gas nozzles 340f and 340g. Furthermore, the second buffer structure 80 is configured to be filled with the purge gas supplied through the gas nozzles 340f and 340g.

In addition, the gas nozzles 340f and 340g are configured to be capable of supplying the purge gas toward the side walls of the first buffer structure 12b, the inner tube 12, or the outer tube 14 such that an inside (inner portion) of the second buffer structure 80 can be set to a high pressure with respect to the opening 236. As a result, it is possible to improve an effect of suppressing the reversing of the gas discharged (exhausted) through the opening 236.

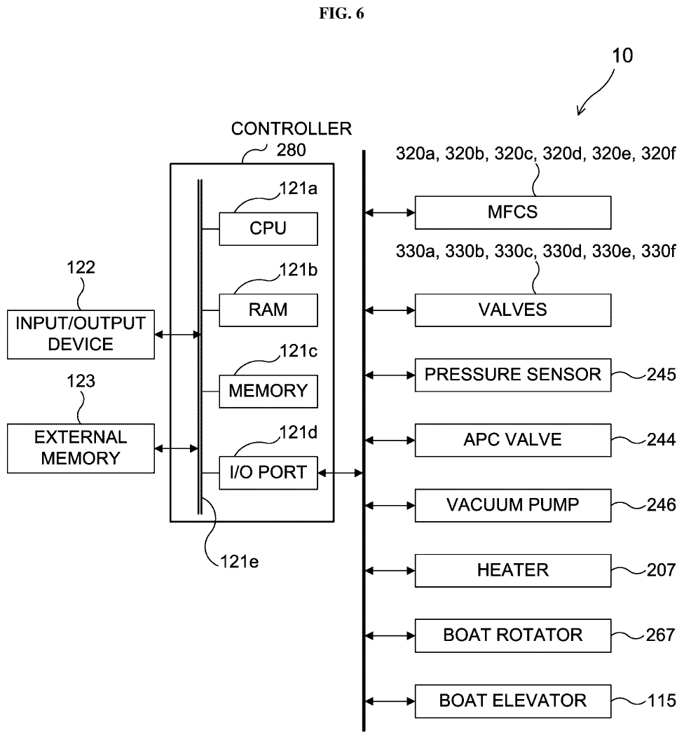

FIG. 6 is a block diagram schematically illustrating the substrate processing apparatus 10. A controller 280 serving as a control structure of the substrate processing apparatus 10 may be embodied by a computer. The computer includes a CPU (Central Processing Unit) 121a, a RAM (Random Access Memory) 121b, a memory 121c and an I/O port (input/output port) 121d.

The RAM 121b, the memory 121c and the I/O port 121d are configured to exchange data with the CPU 121a through an internal bus 121e. For example, an input/output device 122 configured by a component such as a touch panel may be connected to the controller 280.

For example, the memory 121c is configured by a component such as a flash memory and a hard disk drive (HDD). For example, a control program configured to control operations of the substrate processing apparatus 10 or a process recipe containing information on procedures and conditions of a substrate processing described later may be readably stored in the memory 121c.

The process recipe is obtained by combining steps (procedures) of the substrate processing described later such that the controller 280 can execute the steps to acquire a predetermined result, and functions as a program. Hereinafter, the process recipe and the control program may be collectively or individually referred to as a “program.”

Thus, in the present specification, the term “program” may refer to the process recipe alone, may refer to the control program alone, or may refer to both of the process recipe and the control program. The RAM 121b functions as a memory area (work area) where a program or data read by the CPU 121a is temporarily stored.

The I/O port 121d is connected to components mentioned above such as the MFCs 320a to 320f, the valves 330a to 330f, the pressure sensor 245, the APC valve 244, the vacuum pump 246, the heater 207, the temperature sensor, the boat rotator 267 and the boat elevator 115.

The CPU 121a is configured to read and execute the control program stored in the memory 121c, and to read the process recipe stored in the memory 121c in accordance with an instruction such as an operation command inputted via the input/output device 122.

For example, in accordance with contents of the process recipe read from the memory 121c, the CPU 121a is configured to be capable of controlling various operations such as flow rate adjusting operations for various gases by the MFCs 320a to 320f, opening and closing operations of the valves 330a to 330f and an opening and closing operation of the APC valve 244. In addition, the CPU 121a is configured to be capable of controlling various operations such as a pressure adjusting operation by the APC valve 244 based on the pressure sensor 245, a start and stop of the vacuum pump 246 and a temperature adjusting operation by the heater 207 based on the temperature sensor. In addition, the CPU 121a is configured to be capable of controlling various operations such as an operation of adjusting a rotation and a rotation speed of the boat 217 by the boat rotator 267 and an elevating and lowering operation of the boat 217 by the boat elevator 115.

For example, the controller 280 is not limited to a dedicated computer, and may be embodied by a general-purpose computer. For example, the controller 280 according to the present embodiments may be embodied by preparing an external memory 123 storing the program and by installing the program onto the general-purpose computer using the external memory 123. For example, the external memory 123 may include a magnetic disk such as a hard disk, an optical disk such as a CD, a magneto-optical disk such as an MO and a semiconductor memory such as a USB memory.

In addition, a method of providing the program to the computer is not limited to a method using the external memory 123. For example, the program may be provided directly to the computer by a communication interface such as the Internet and a dedicated line instead of the external memory 123. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123.

### Example of Present Embodiments

Subsequently, an overview of operations of the substrate processing apparatus 10 according to the present embodiments will be described in accordance with a control procedure performed by the controller 280 when executing the process recipe. In addition, the boat 217 on which a predetermined number of wafers 200 are placed in advance is inserted into the reaction tube 203, the reaction tube 203 is airtightly closed with the lid 219, and the vacuum pump 246 and APC valve 244 are operated to exhaust an atmosphere (inner atmosphere) of the reaction tube 203 through the exhaust port 230 such that a pressure (inner pressure) of the reaction tube 203 is adjusted to a predetermined level. The process recipe may further include such a boat loading and such a pressure adjusting.

For example, the controller 280 opens the valves 330b and 330f to supply the source gas through the gas nozzle 340b serving as an example of a second gas nozzle. When supplying the sourced gas, the controller 280 closes the valve 330a and opens the valves 330c to 330f to supply the N₂ gas serving as the inert gas through the gas nozzles 340a and 340c to 340e to process the wafer 200 (first processing procedure).

When performing the first processing procedure, the controller 280 operates the vacuum pump 246 and the APC valve 244 such that a pressure detected (obtained) from the pressure sensor 245 becomes constant and such that the inner atmosphere of the reaction tube 203 is exhausted through the exhaust port 230. As a result, a mixed gas (that is, a gaseous mixture) of the source gas and the inert gas flows in parallel to an upper surface of the wafer 200, then flows from an upper portion to the lower portion of the gap S through the opening 236 and the second gas exhaust port 237, and is exhausted through the exhaust pipe 231 via the exhaust port 230.

In particular, a part of the mixed gas exhausted through the opening 236 flows back (diffuses) in the gap S without flowing toward the exhaust port 230. According to of the present embodiments, by using the first gap 90 formed between the first buffer structure 12b and the outer tube 14, it is possible to suppress a diffusion of the mixed gas in front of the first buffer structure 12b. As a result, the mixed gas flows in parallel to an upper surface of the wafer 200, then flows from the upper portion to the lower portion of the gap S through the opening 236, and is exhausted through the exhaust pipe 231 via the exhaust port 230.

In such a processing procedure, the inert gas is supplied through the gas nozzles 340a and 340c to 340e toward the center of the wafer 200. When supplying the inert gas, the controller 280 controls a supply amount of the inert gas supplied through each of the gas nozzles 340a and 340c to 340c. Thereby, it is possible to adjust a concentration of the inert gas such that the concentration of the inert gas in the center (central portion) of the wafer 200 is set to be lower than the concentration of the inert gas in an outer periphery (outer peripheral portion) of the wafer 200. As a result, since a supply amount of the source gas to the center of the wafer 200 can be controlled, it is possible to set (or change) a thickness distribution of a layer (which is formed on the wafer 200 by the source gas) within the surface of the wafer 200 from a central concave distribution toward a flat distribution or a central convex distribution.

In addition, in such a processing procedure, the controller 280 controls the supply amount of the inert gas supplied through each of the gas nozzles 340f and 340g, for example, by filling the second buffer structure 80 with the inert gas. Thereby, it is possible to set (or adjust) a pressure (inner pressure) of the second buffer structure 80 to be higher than that of the opening 236. As a result, it is possible to suppress a flow of a part of the mixed gas diffusing back into the gap S. In addition, it is possible to discharge (exhaust) the gas through the exhaust port 230 without stagnation. For example, the inert gas may be supplied through the gas nozzles 340f and 340g toward the first gap 90.

After a predetermined time has elapsed, when the first processing procedure is completed, the controller 280 closes the valve 330b to stop a supply of the source gas supplied through the gas nozzle 340b, and opens the valve 330f to supply the inert gas through the gas nozzle 340b. In addition, the controller 280 controls the vacuum pump 246 and the APC valve 244 to increase a negative pressure supplied to the reaction tube 203 such that the inner atmosphere of the reaction tube 203 is exhausted through the exhaust port 230 (exhaust procedure).

Then, when exhausting the inner atmosphere of the reaction tube 203, a supply of the inert gas through each of the gas nozzles 340f and 340g is stopped. Simultaneously, the controller 280 opens the valves 330a and 330c to supply the inert gas through the gas nozzles 340a and 340c while exhausting the gas through the exhaust port 230, and the gas remaining in the gap S between the inner tube 12 and the outer tube 14 is purged out through the exhaust port 230 (discharge procedure).

When the processing of the wafer 200 is completed by performing the first processing procedure to the discharge procedure described above, the boat 217 is transferred (unloaded) from the reaction tube 203 by performing a procedure in an order reverse to that of the boat loading mentioned above. The wafers 200 are transferred from the boat 217 to a pod on a transfer shelf (not shown) by a wafer transfer structure (not shown). Then, the pod is transferred from the transfer shelf to a pod stage by a pod transfer structure (not shown), and is unloaded out of a housing of the substrate processing apparatus 10 by an external transfer structure (not shown).

### First Modified Example

For example, after the first processing procedure, the controller 280 may open the valves 330a and 330e to supply the reactive gas (for example, a gas such as a nitrogen-containing material and an oxygen-containing material) through the gas nozzle 340a. In such a case, simultaneously, the controller 280 may close the valve 330b and open the valves 330c, 330d and 330f to supply the nitrogen (N₂) gas serving as the inert gas through the gas nozzles 340a, 340c, 340d and 340f to process the wafer 200 (second processing procedure).

When performing the first processing procedure, a part of a mixed gas of the reactive gas and the inert gas discharged through the opening 236 may flow back through the gap S without flowing toward the exhaust port 230. Similar to the first processing procedure, by using the first gap 90 formed between the first buffer structure 12b and the outer tube 14, it is possible to suppress a diffusion of the mixed gas in front of the first buffer structure 12b. In addition, the controller 280 controls the supply amount of the inert gas supplied through each of the gas nozzles 340f and 340g. Thereby, it is possible to set (or adjust) the inner pressure of the second buffer structure 80 to be higher than that of the opening 236. As a result, it is possible to suppress a flow of a part of the mixed gas diffusing back into the gap S.

After a predetermined time has elapsed, when the second processing procedure is completed, the exhaust procedure mentioned above is performed, and the supply of the inert gas supplied through each of the gas nozzles 340f and 340g is stopped. Then, the discharge procedure mentioned above is performed.

### Second Modified Example

Subsequently, in a step of supplying the source gas to the wafer 200 in the process chamber 201 (that is, in the first processing procedure), first, the valves 330b and 330f are opened. The source gas is supplied to a storage (storage vessel) (not shown) through the gas supply pipes 310b and 310f. A source material of the source gas is stored in the storage and heated by a heater (not shown) to be vaporized. The source material vaporized into a gaseous state (that is, the source gas) is then supplied to the gas supply pipes 310b and 310f with a flow rate of the source gas adjusted by the MFCs 320b and 320f. The source gas is supplied to the process chamber 201 through the gas supply holes 234b of the gas nozzle 340b, and then exhausted through the exhaust port 230.

In such a state, the source gas discharged through the opening 236 then travels straight through the gap S and collides with the outer tube 14. Then, a part of the source gas diffuses in the gap S along the outer tube 14 without flowing toward the exhaust port 230. In other words, in the flash supply of the example of the present embodiments, a large amount of the source gas may diffuse in the gap S without flowing toward the exhaust port 230.

However, even in such a case, as in the first processing procedure mentioned above, by using the first gap 90 formed between the first buffer structure 12b and the outer tube 14, it is possible to suppress a diffusion of the source gas in front of the first buffer structure 12b. In addition, the controller 280 controls the supply amount of the inert gas supplied through each of the gas nozzles 340f and 340g. Thereby, it is possible to set (or adjust) the inner pressure of the second buffer structure 80 to be higher than that of the opening 236. As a result, it is possible to suppress a flow of a part of the source gas diffusing back into the gap S. Thereby, it is possible to enhance an exhaust of the source gas.

According to the present embodiments, it is possible to obtain one or more of the following effects.
(a) When viewed from above, the width W1 of the first gap 90 formed between the outer wall 70 of the first buffer structure 12b and the outer tube 14 is set to be narrower than the width W2 of the second gap 92 formed between the inner tube 12 and the outer tube 14 within a region extending from beside the outer wall 70 of the first buffer structure 12b to the opening 236. Therefore, it is possible to reduce the conductance between the outer wall 70 of the first buffer structure 12b and the outer tube 14. That is, in the gap S between the inner tube 12 and the outer tube 14, it is possible to set a pressure related to the nozzle arrangement chamber 222 to a positive pressure relative to a pressure related to the exhaust port 230. Therefore, it is possible to suppress the reversing of an exhaust gas (that is, the gas exhausted as described above) discharged through the opening 236. As a result, it is possible to suppress an adhesion and a generation of by-products inside the reaction tube 203, and it is also possible to reduce a generation of particles.
(b) In addition, the gas nozzles 340f and 340g are configured to be capable of supplying the purge gas toward the first gap 90 formed between the first buffer structure 12b and the outer tube 14. As a result, it is possible to enhance an effect of suppressing the reversing of the exhaust gas discharged through the opening 236, and it is possible to suppress the stagnation of the exhaust gas even when the reversing of the exhaust gas occurs. In addition, it is possible to reduce a flow rate of the purge gas as compared with a case where the first gap 90 is not formed as in the embodiments of the present disclosure.
(c) Even when the reversing of the exhaust gas discharged through the opening 236 occurs due to a high flow rate supply (flash supply), according to the configuration of the present embodiments, the width W1 of the first gap 90 is set to be narrower than other widths formed between the inner tube 12 and the outer tube 14 when viewed from above, and the width W1 is constant between the outer wall 70 of the first buffer structure 12b along the outer tube 14. Thereby, it is possible to reduce the conductance between the outer wall 70 of the first buffer structure 12b and the outer tube 14. Therefore, it is possible to suppress the reversing of the exhaust gas discharged through the opening 236.

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

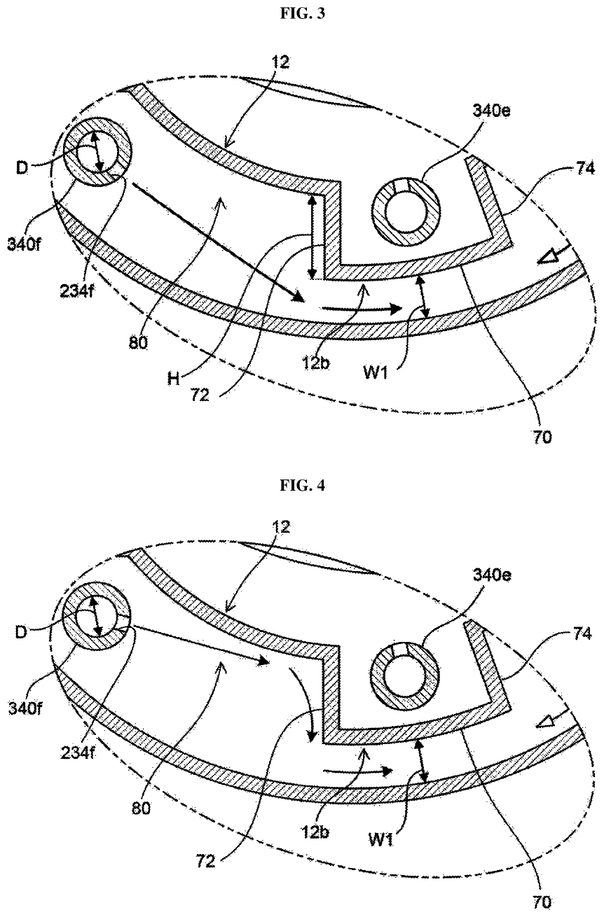

For example, the embodiments mentioned above are described by way of an example in which the gas nozzle 340f is configured to supply the purge gas toward the first gap 90 corresponding to the lower one of the first buffer structures 12b in FIG. 3. However, the technique of the present disclosure is not limited to such a configuration. For example, the gas nozzle 340f may be configured to supply the purge gas toward the inner tube 12, the outer tube 14 or the side wall 72 of the first buffer structure 12b. In addition, the gas nozzle 340f may be configured to be capable of supplying the purge gas in a direction inclined with respect to a direction from the second buffer structure 80 toward the opening 236 along the outer tube 14. In an example shown in FIG. 4, the gas nozzle 340f ejects the purge gas toward the side wall 72 of the first buffer structure 12b. According to such a configuration, it is possible to supply the purge gas through the gas nozzle 340f toward the side wall 72 of the first buffer structure 12b, the inner tube 12 or the outer tube 14, and it is also possible to set the inside of the second buffer structure 80 to a high pressure with respect to the opening 236. As a result, it is possible to improve the effect of suppressing the reversing of the exhaust gas discharged through the opening 236. It is also possible to obtain substantially the same effect with the gas nozzle 340g.

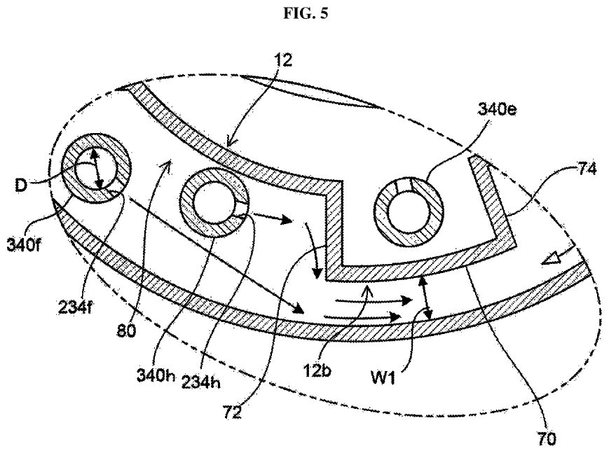

For example, the embodiments mentioned above are described by way of an example in which one gas nozzle is disposed in each of the second buffer structures 80. However, the technique of the present disclosure is not limited to such a configuration. For example, a plurality of gas nozzles may be disposed in one of the second buffer structures 80. For example, as shown in FIG. 5, the gas nozzle 340f through which the purge gas is ejected to the first gap 90 and a gas nozzle 340h through which the purge gas is ejected toward the side wall 72 of the first buffer structure 12b may be disposed in the second buffer structure 80. With such a configuration, it is possible to supply the purge gas through the gas nozzle 340f toward the first gap 90, and it is also possible to supply the purge gas through the nozzle 340h toward the side wall 72 of the first buffer structure 12b, the inner tube 12, or the outer tube 14. Thereby, it is possible to set the inside of the second buffer structure 80 to a high pressure with respect to the opening 236. As a result, it is possible to improve the effect of suppressing the reversing of the exhaust gas discharged through the opening 236. In addition, by arranging a plurality of gas nozzles in the other one of the second buffer structures 80 and adjusting an ejection direction of the purge gas supplied through each of the plurality of gas nozzles, it is possible to obtain substantially the same effect as in the case mentioned above.

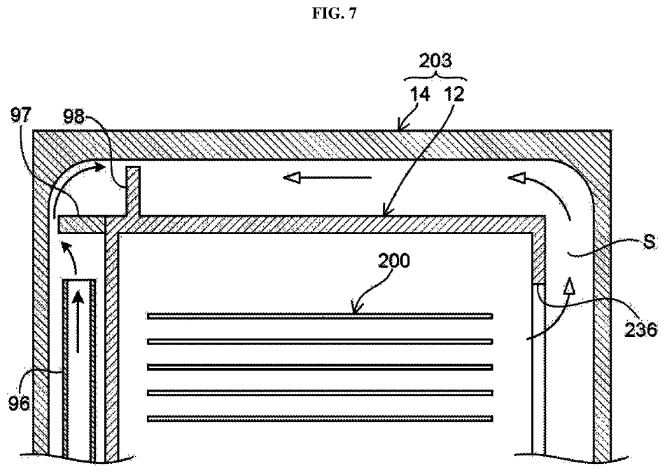

In addition, a part of the gas nozzles arranged in each of the second buffer structures 80 may be configured as a gas nozzle 96 through which the purge gas is supplied toward a region (area) between the ceiling of the outer tube 14 and the ceiling of the inner tube 12. When using the gas nozzle 96, for example, as shown in FIG. 7, a baffle plate 97 extending from the upper portion of the inner tube 12 toward the outer tube 14 is provided, and a baffle plate 98 extending from the ceiling of the inner tube 12 toward the ceiling of the outer tube 14 is provided. In addition, a gap is formed (provided) between the baffle plate 97 or 98 and the outer tube 14. In such a case, the gas nozzle 96 is configured to be capable of supplying the purge gas toward the exhaust gas that has intruded into the region between the ceiling of the outer tube 14 and the ceiling of the inner tube 12. As a result, it is possible to enhance an effect of suppressing the exhaust gas around the area, and it is also possible to improve an exhaust efficiency.

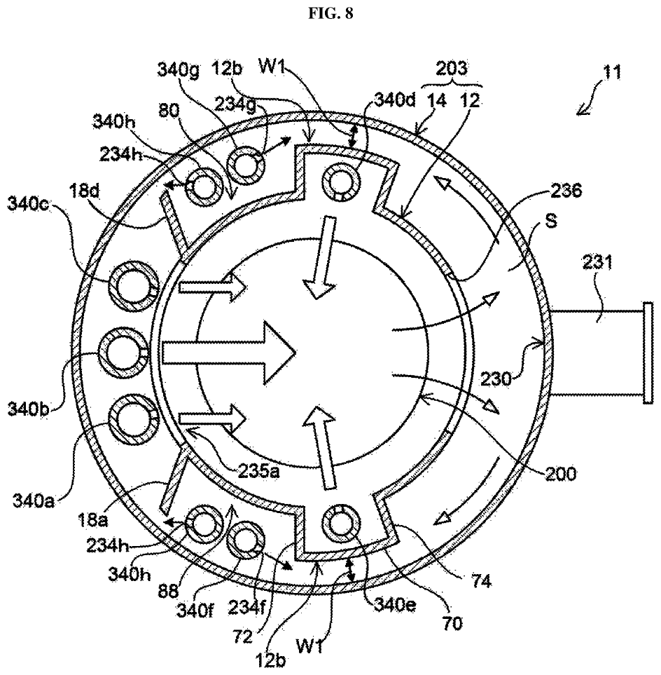

As shown in FIG. 8, the process chamber 201 may be provided with the partition plates 18a and 18d and the gas nozzles 340a to 340e configured to be capable of supplying the source gas to the process chamber 201 by a side flow. The second buffer structure 80 is formed so as to be surrounded by the inner tube 12, the outer tube 14, the side wall 72 of the first buffer structure 12b and the partition plate 18a or 18d. By adopting such a configuration, it is possible to suppress the diffusion (or a flow) of the source gas into the second buffer structure 80 due to a leakage through the gas nozzles 340a to 340c.

For example, the embodiments mentioned above are described by way of an example in which a film forming process of a semiconductor device is performed by the processing apparatus. However, the technique of the present disclosure is not limited thereto. That is, the technique of the present disclosure may be applied not only to the film forming process mentioned above but also to other film forming processes of forming other films such as an oxide film, a nitride film and a film containing a metal. In addition, the specific contents of the film forming process are not limited to those exemplified in the embodiments mentioned above. For example, in addition to or instead of the film forming process mentioned above, the technique of the present disclosure may also be applied to a substrate processing such as an annealing process, an oxidation process, a nitridation process, a diffusion process and a lithography process. In addition, the technique of the present disclosure may also be applied to other substrate processing apparatuses such as an annealing apparatus, an oxidation apparatus, a nitridation apparatus, an exposure apparatus, a coating apparatus, a drying apparatus, a heating apparatus, and an apparatus using a plasma. For example, the technique of the present disclosure may also be applied when a combination of such substrate processing apparatuses is provided.

The technique of the present disclosure may also be applied when a constituent of one of the embodiments mentioned above is substituted with another constituent of another embodiment, or when a constituent of one of the embodiments mentioned above is added to another embodiment. In addition, the technique of the present disclosure may also be applied when the constituent of the embodiments mentioned above is omitted or substituted, or when a constituent is added to the embodiments mentioned above.

According to some embodiments of the present disclosure, it is possible to suppress the reversing of the exhaust gas exhausted from the process chamber.

What is claimed is:

1. A process vessel comprising:
an inner tube provided with an opening through which a process gas is exhausted from a process chamber and a first buffer structure in which a first supplier configured to supply the process gas into the process chamber is disposed;
an outer tube disposed outside the inner tube; and
a second buffer structure provided along the outer tube to be opposite to the opening with the first buffer structure interposed therebetween and surrounded by the inner tube, the outer tube and a side wall of the first buffer structure,
wherein, when viewed from above, a width of a first gap formed between an outer wall of the first buffer structure and the outer tube is set to be narrower than a width of a second gap formed between the inner tube and the outer tube within a region extending from beside the first buffer structure to the opening.

2. The process vessel of claim 1, wherein, when viewed from above, the width of the first gap is configured to be constant along the outer tube.

3. The process vessel of claim 2, wherein the outer wall of the first buffer structure is configured in a manner concentric with the outer tube.

4. The process vessel of claim 1, wherein the first gap is provided between both of side walls of the first buffer structure.

5. The process vessel of claim 1, wherein the width of the first gap is configured to narrow toward the second buffer structure along the outer tube when viewed from above.

6. The process vessel of claim 1, wherein a second supplier configured to supply a purge gas is disposed in the second buffer structure, and
wherein the width of the first gap is configured to be smaller than a flow path diameter of the second supplier.

7. The process vessel of claim 6, wherein a width between both of side walls of the first buffer structure is configured to be larger than the flow path diameter of the second supplier.

8. The process vessel of claim 1, wherein a second supplier configured to supply a purge gas is disposed in the second buffer structure, and
wherein the second supplier is further configured to be capable of supplying the purge gas in a direction inclined with respect to a direction from the second buffer structure toward the opening along the outer tube.

9. The process vessel of claim 8, wherein the second buffer structure is configured to be capable of being filled with the purge gas.

10. The process vessel of claim 9, wherein the second supplier is further configured to supply the purge gas toward the inner tube, the outer tube or the side wall of the first buffer structure.

11. The process vessel of claim 9, wherein the second supplier is disposed in vicinity of the first buffer structure.

12. The process vessel of claim 8, wherein the second supplier is further configured to supply the purge gas toward the first gap.

13. The process vessel of claim 8, wherein one or more second suppliers are disposed in the second buffer structure.

14. The process vessel of claim 13, wherein the one or more second suppliers comprise: a first purge nozzle through which the purge gas is supplied toward the inner tube, the outer tube or the side wall of the first buffer structure; and a second purge nozzle through which the purge gas is supplied toward a region between a ceiling of the outer tube and a ceiling of the inner tube.

15. The process vessel of claim 1, wherein a third supplier configured to be capable of supplying the process gas by a flash flow is disposed in the process chamber.

16. The process vessel of claim 15, wherein second supplier configured to supply a purge gas is disposed in the second buffer structure, and
wherein the second supplier is further configured to be capable of supplying the purge gas toward a third gap formed between the third supplier and the inner tube.

17. The process vessel of claim 1, wherein a third supplier configured to be capable of supplying the process gas by a side flow is disposed in the process chamber, and
wherein the second buffer structure is formed so as to be surrounded by the inner tube, the outer tube, the side wall of the first buffer structure and the third supplier.

18. A processing apparatus comprising:
a process vessel,
wherein the process vessel comprises:
an inner tube provided with an opening through which a process gas is exhausted from a process chamber and a first buffer structure in which a first supplier configured to supply the process gas into the process chamber is disposed;
an outer tube disposed outside the inner tube; and
a second buffer structure provided along the outer tube to be opposite to the opening with the first buffer structure interposed therebetween and surrounded by the inner tube, the outer tube and a side wall of the first buffer structure,
wherein, when viewed from above, a width of a first gap formed between an outer wall of the first buffer structure and the outer tube is set to be narrower than a width of a second gap formed between the inner tube and the outer tube within a region extending from beside the first buffer structure to the opening.

19. A substrate processing method comprising:
(a) loading a substrate into a process vessel, wherein the process vessel comprises:
an inner tube provided with an opening through which a process gas is exhausted from a process chamber and a first buffer structure in which a first supplier configured to supply the process gas into the process chamber is disposed;
an outer tube disposed outside the inner tube; and
a second buffer structure provided along the outer tube to be opposite to the opening with the first buffer structure interposed therebetween and surrounded by the inner tube, the outer tube and a side wall of the first buffer structure,
wherein, when viewed from above, a width of a first gap formed between an outer wall of the first buffer structure and the outer tube is set to be narrower than a width of a second gap formed between the inner tube and the outer tube within a region extending from beside the first buffer structure to the opening; and
(b) supplying the process gas to the substrate to perform a predetermined processing.

20. A method of manufacturing a semiconductor device comprising:
the method of claim 19,
wherein, when performing the predetermined processing, a source gas is supplied to the substrate via a storage vessel provided in a source gas supply line through which the source gas is supplied to the process chamber, and
wherein the storage vessel is configured to be capable of temporarily storing the source gas therein.
